(19) United States
(12) Patent Application Publication
(10) Pub. No.: US 2009/0190300 A1
(43) Pub. Date: Jul. 30, 2009

(54) PARTS SUPPORT APPARATUS

(75) Inventors: Kazuaki Takao, Kawasaki (JP); Kazuya Orui, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/238,595

(22) Filed: Sep. 26, 2008

(30) Foreign Application Priority Data
Jan. 25, 2008 (JP) 2008-015030

(51) Int. Cl. G06F 1/16; H05K 7/00

(52) U.S. Cl. 361/679.43; 361/809

(57) ABSTRACT

A module is inserted from an aperture of a parts support apparatus into a part support hole, and further pushed into a cavity innermost the part support hole until a insertion side end portion is engaged in the cavity. After the module is engaged into the part support hole, an effect of force of dropping off upward the module from contact points inside on upper and lower surfaces is suppressed by the cavity, and the module can be supported by the parts support apparatus only. After the attachment of the module, a projection unit provided on the lower surface of a housing of a body device lowers with the housing, touches an end surface opposite the insertion side of the module to protect the module from dropping off the cavity in the horizontal direction.

### BACKGROUND OF THE INVENTION

1. Field of the Invention

The present invention relates to a parts support apparatus for supporting parts.

2. Description of the Related Art

Generally, a number of computers are designed to be provided with an attached expansion module. Not only a large computer, but also a notebook PC (personal computer) can be, for example, a card type expansion module for wireless communications.

FIGS. 1A through 1C show the procedure of attaching the card type expansion module on the main board of a notebook PC.

The printed circuit and other electronic parts are omitted for a main board 1 shown in FIGS. 1A through 1C.

As shown in FIG. 1A, a pair of a socket unit 2 and a latch unit 3 forms an attachment unit 4 for attachment of a card type expansion module on the main board 1.

When the card type expansion module is attached to the attachment unit 4, a card type expansion module 5 is diagonally held by hand (the hand is omitted in the attached drawings) as shown in FIG. 1B, and the insertion side end portion of the card type expansion module 5 is inserted into the insertion unit of the socket unit 2.

A number of contact points 8 and 9 for connection of a number of contact points provided for the card type expansion module 5 to other electronic parts loaded into the main board 1 are provided above and below the insertion unit for the socket unit 2 as shown in FIG. 1A. These contact points 8 and 9 are made of a conductive spring member.

As shown in FIG. 1B, the card type expansion module 5 is diagonally inserted and engaged into the insertion unit of the socket unit 2 as indicated by the arrow a, and the card type expansion module 5 is pushed downward as indicated by the arrow b.

Then, as shown in FIG. 1C, latches 7a and 7b provided at the end portions on both sides of the latch unit 3 are engaged in the engaging unit of a fixing unit 6 provided at the end portion opposite the insertion side end portion of the card type expansion module 5. Thus, the card type expansion module 5 is fixed to the attachment unit 4.

Since the expansion module 5 is first diagonally inserted into the insertion unit as shown in FIG. 1B, the contact point 8 provided above and contacting the contact point on the upper surface of the insertion side end portion of the expansion module 5 is positioned a little behind the contact point 9 provided below and contacting the contact point on the lower surface of the insertion side end portion of the expansion modules as shown in FIG. 1A in a number of contact points 8 and 9 provided above and below the insertion unit of the socket unit 2.

Since these contact points 8 and 9 are made of a conductive spring member as described above, they contact the contact point of the expansion module 5, and have the urging force to press the contact portion. Thus, the contact between the contact points, that is, the electric connection can be maintained without fail.

On the other hand, the upper contact point 8 arranged below and behind the insertion unit urges downward the insertion side end portion of the expansion module 5, and the contact point 9 arranged forward the insertion unit urges upward the insertion side end portion of the expansion module 5. Therefore, the force of diagonally lifting the expansion module 5 inserted into the socket unit 2 constantly works.

Under the condition, the expansion module 5 is diagonally lifted and dropped off the socket unit 2. To suppress the event, the latch unit 3 is arranged to press the end portion opposite the insertion unit of the expansion module 5 as described above,

If the attachment unit 4 of the card type expansion module is divided into a module contact point connection unit (socket unit 2) and a module fixing unit (latch unit 3), then the socket unit 2 and the latch unit 3 are individual parts. Therefore, when they are implemented to the main board 1, they are separately soldered.

By thus separately soldering them, the implementation displacement of the socket unit 2 and the latch unit 3 in the directions of X, Y, and θ toward the main board 1 occurs at random without mutual correlation.

With the random implementation displacement, there occur the problems of hard engagement when the expansion module 5 is fixed to the latch unit 3, easy drop-off of the expansion module 5 from the attachment unit 4 by a shock, etc.

If a unitary structure of the socket unit 2 and the latch unit 3 is designed to prevent the above-mentioned random implementation displacement between the socket unit 2 and the latch unit 3, there occurs no implementation displacement between the socket unit 2 and the latch unit 3. However, each part becomes larger, and requires a larger area on the main board 1.

This refers to a large main board 1, and it is not preferable that the body device of a personal computer etc. provided with the main board 1 also becomes larger.

Originally, a latch is required when the expansion module 5 is engaged into an attachment unit, the expansion module 5 is inserted into the socket unit 2 diagonally from above, further pressed downward, and the contact point of the upper and lower surfaces of the expansion module 5 is made to contact the contact point of the inside upper and lower surfaces of the socket unit 2.

That is, when the expansion modules is inserted diagonally from above, the arrangement of the contact point of the inside upper and lower surfaces of the socket unit 2 is displaced forward and backward. Therefore, after the expansion module 5 has been engaged, the force of dropping off the expansion module 5 upward constantly works on the expansion module 5 from the contact point of the inside upper and lower surfaces of the socket unit 2.

When the insertion of the expansion module 5 diagonally from above is replaced with the insertion in the horizontal direction with respect to the socket unit 2, it is not necessary to displace forward and backward the contact points of the inside upper and lower surfaces of the socket unit 2, and the upper and lower surfaces can be similarly arranged, thereby generating no force of constantly dropping off the expansion module 5 upward.

However, with the above-mentioned configuration, an additional space is required on the main board 1 to insert and remove the expansion module in the horizontal direction with respect to the attachment unit. In this case, there occurs the problem that a large area is required for the socket unit on the main board 1.

### SUMMARY

According to the present embodiments, the parts support apparatus has the following.

A part support hole for hold an aperture capable of inserting a part.

A cavity is provided in the part support hole and can be engaged with a part of the part inserted from the aperture into the part support hole.

### BRIEF DESCRIPTION OF THE DRAWINGS

FIGS. 1A through 1C show the procedure of attaching a conventional card type expansion module to the main board of a notebook PC;

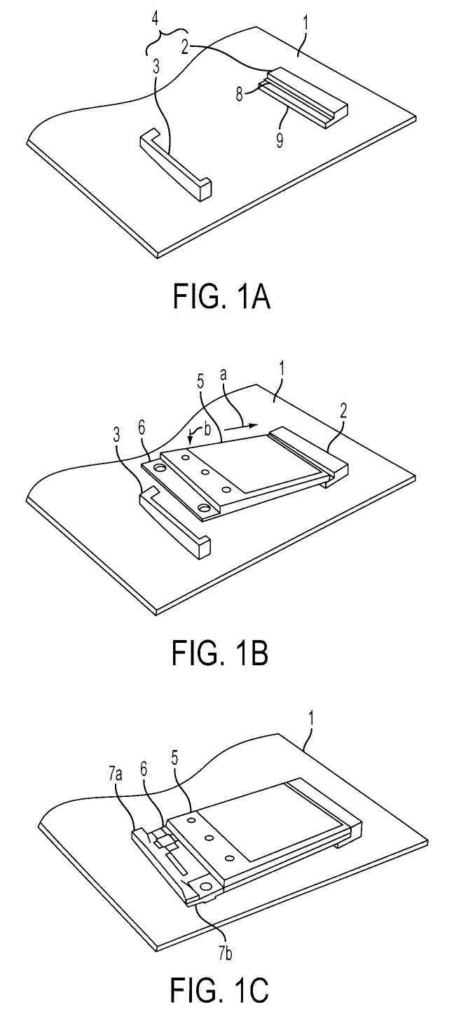

FIGS. 2A and 2B are side sectional views showing the configuration of the parts support apparatus according to the first embodiment and the operation states when the expansion module is attached, and FIG. 2C shows the arrangement of the stopper after the expansion module is attached;

FIG. 3 is a side sectional view of the configuration of the parts support apparatus according to the second embodiment; and

FIG. 4 is a plan view of the configuration of the parts support apparatus according to the third embodiment.

### DESCRIPTION OF THE PREFERRED EMBODIMENTS

The embodiments are described below in detail with reference to the attached drawings.

### First Embodiment

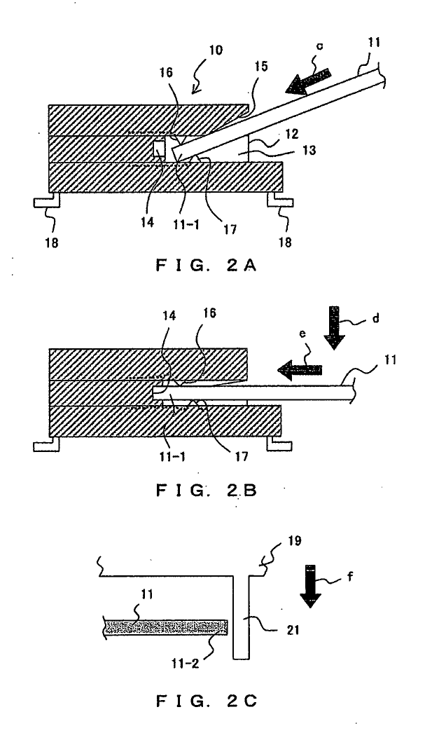

FIGS. 2A and 2B are side sectional views showing the configuration of the parts support apparatus according to the first embodiment and the operation states when the expansion module is attached. FIG. 2C shows the arrangement of the stopper after the expansion module is attached. A parts support apparatus 10 according to the first embodiment is to attach a card type expansion module etc., and is implemented on the main board of a personal computer etc.

As shown in FIG. 2A, the parts support apparatus 10 includes a part support hole 13 having an aperture 12 into which an expansion module 11 (hereinafter referred to simply as a module) as a part can be inserted, and a cavity 14 in which a part of the module 11 inserted into the part support hole 13 from the aperture 12 can be engaged. The height of the aperture of the cavity 14 is designed to be a little higher than the thickness of the module 11.

The part support hole 13 into which the module 11 is to be inserted is basically designed as a rectangular parallelepiped or a cube. On the inside upper surface, a slope 15 is formed so that the module 11 can be easily inserted diagonally from above as indicated by the arrow c.

The above-mentioned cavity 14 is provided in the position in which the cavity 14 can be engaged with an insertion side end portion 11-1 of the module 11 when the module 11 is inserted into the innermost of the part support hole 13.

The module 11 is a planar part, and a plurality of contact points are provided on the upper and lower surfaces of the insertion side end portion 11-1 inserted into the part support hole 13 although the contact points are not shown in the attached drawings.

Another part support hole 13 is provided with a plurality of contact points 16 and 17 respectively touching the plurality of contact points provided on the insertion side end portion 11-1 of the module 11. The parts support apparatus 10 having the part support hole 13 is fixed to the main board (not shown in the attached drawings) with fixing legs 18.

The contact points 16 and 17 of the part support hole 13 is arranged with the arrangement of the contact points on the inside upper and lower surfaces in the part support hole 13 displaced forward and backward corresponding to the insertion performed diagonally from above into the part support hole 13 of the module 11.

That is, the contact points 16 on the upper surface is arranged a little inward of the part support hole 13, and the contact points 17 on the lower surface are arranged toward the aperture. Therefore, as shown in FIG. 2B, after the engagement of the module 11 into the part support hole 13, the force of dropping off the module 11 upward works on the module 11 from the contact points 16 and 17 on the upper and lower surfaces inside the 13.

However, in the present embodiment, since the insertion side end portion 11-1 of the module 11 is engaged in the cavity 14 inward the part support hole 13 as shown in FIG. 2B, the operation of the force of dropping off the module 11 upward is suppressed by the cavity 14 and does not work.

Thus, in the structure of the parts support apparatus 10 of the present embodiment, the module 11 can be supported only by the parts support apparatus 10 as a socket unit.

However, in this state, there is the possibility that the module 11 drops off from the cavity 14 in the horizontal direction, and slips off the part support hole 13. Therefore, the present embodiment is provided with a drop protection member for avoiding the drop-off.

That is, in attaching and detaching the module 11, the housing of the body device of the personal computer etc. to which the module 11 is attached is to be opened or closed. In the present embodiment, as shown in FIG. 2C, a projecting unit 21 is arranged on the lower surface of a housing 19 of the body device that opens and closes up and down.

As described above, after the module 11 is attached to the part support hole 13 of the parts support apparatus 10, the housing 19 of the body device is closed to lower the projecting unit 21 provided on the lower surface of the housing 19 with the housing 19 as indicated by the arrow f. Then, the side of the projecting unit 21 touches an opposite end portion 11-2 to the insertion side of the module 11, thereby suppressing the module 11 from dropping off from the cavity 14 in the horizontal direction.

Thus, the drop protection member provided on the lower surface of the housing 19 of the body device is separate from the attachment unit with the housing 19 of the body device, and lowers to the drop protection position after the attachment of the module 11. Therefore, the part loaded area is not consumed on the main board not shown in the attached drawings

As described above, according to the present embodiment, only the parts support apparatus 10 having the function of a socket can be arranged on the main board, and the projecting unit 21 can be arranged in the contact point 9 of the body device to eliminate the necessity to provide a latch unit as a member independent of the parts support apparatus 10.

Thus, the cost of the attachment unit of the module 11 can be reduced, and the erroneous attachment by the implementation displacement caused when the attachment unit is divided into two different members can be avoided.

In addition, in a narrower arrangement area of the attachment unit, the module 11 can be fixed by the single parts support apparatus 10 in the conventional attaching method of pushing the module 11 downward while inserting the module 11 diagonally from above into the attachment unit.

### Second Embodiment

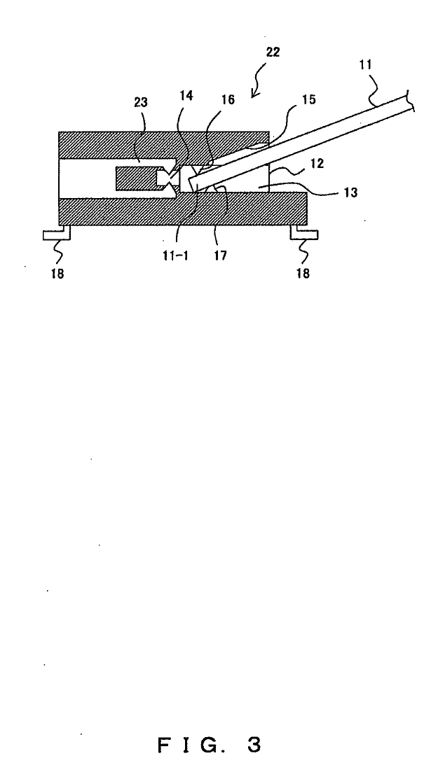

FIG. 3 is a side sectional view of the configuration of the parts support apparatus according to the second embodiment. In FIG. 3, the same configuration portion in FIGS. 2A and 2B are assigned the same reference numerals as in FIGS. 2A and 2E.

As shown in FIG. 3, a parts support apparatus 22 according to the present embodiment is provided with a latch pair 23 as a drop protection member for enclosing into the cavity 14 inward the part support hole 13 from up and down the insertion side end portion 11-1 of the module 11 inserted into the cavity 14, and fixing the position.

Although not shown in the attached drawings, a latch engagement unit is formed at the position corresponding to the latch pair 23 on the upper and lower surfaces of the insertion side end portion 11-1 of the module 11. If the module 11 is further pushed inward the part support hole 13 from the diagonal insertion position shown in FIG. 3, and the insertion side end portion 11-1 is inserted into the cavity 14, then the latch pair 23 is engaged in the latch engagement unit of the module 11 to prevent the module 11 from dropping off the part support hole 13.

Since a slope is formed in the directions of attachment and detachment on the engagement surface of the latch pair 23 with respect to the latch engagement unit, the module 11 can be easily detached from the part support hole 13 only by pulling the module 11 in the horizontal direction by the length of the depth of the cavity 14.

Thus, according to the present embodiment, only the parts support apparatus 22 having the function of a socket can be arranged on the main board to eliminate the necessity to provide a separate latch unit independent of the parts support apparatus 22.

Thus, the cost of the attachment unit of the module 11 can be reduced, and the erroneous attachment by the implementation displacement caused when the attachment unit is divided into two different members can be avoided.

In addition, in a narrower arrangement area of the attachment unit, the module 11 can be fixed by the single parts support apparatus 22 in the conventional attaching method of pushing the module 11 downward while inserting the module 11 diagonally from above into the attachment unit.

### Third Embodiment

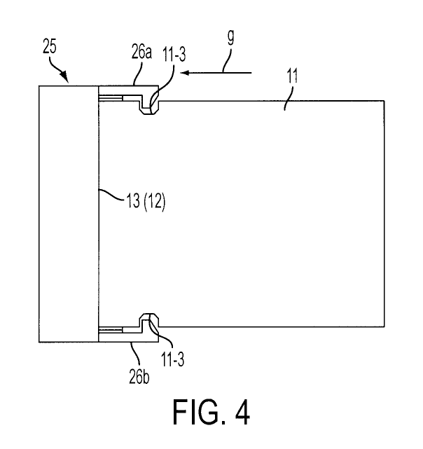

FIG. 4 is a plan view of the configuration of the parts support apparatus according to the third embodiment. In FIG. 4, the same configuration portion in FIGS. 2A and 2B are assigned the same reference numerals as in FIGS. 2A and 2B. The configuration of the side section of the parts support apparatus according to the present embodiment is the same as in FIGS. 2A and 2B.

As shown in FIG. 4, a parts support apparatus 25 is provided with latches 26a and 26b extending opposite the insertion of the module 11 indicated by the arrow g from both sides of the part support hole 13. The latches 26a and 26b are designed to opened and closed in a manual operation.

In the present embodiment, when the module 11 is inserted from the part support hole 13 and the module 11 is completely inward the cavity 14 not shown in FIG. 4, the latch engagement units 11-3 are formed on both sides of the module 11 at the positions corresponding to the latches 26a and 26b.

When the module 11 is attached, the latches 26a and 26b are engaged in the latch engagement unit 11-3 only by pushing the module 11 into the cavity 14 of the part support hole 13, thereby preventing the module 11 from dropping off the part support hole 13.

When the module 11 is detached, the module 11 is pulled out by releasing the engagement of the module 11 with the latch engagement unit 11-3 by horizontally opening the latches 26a and 26b in a manual operation. After pulling out the module 11, the latches 26a and 26b are returned to the original positions.

Thus, according to the present embodiment, the module 11 can be supported by a single parts support apparatus 25 as a socket unit without providing a separate latch unit independent of the parts support apparatus 25 by providing only the parts support apparatus 25 having the function of a socket.

Thus, the cost of the attachment unit of the module 11 can be reduced, and the erroneous attachment by the implementation displacement caused when the attachment unit is divided into two different members can be avoided.

In addition, in a narrower arrangement area of the attachment unit, the module 11 can be fixed by the single parts support apparatus 25 in the conventional attaching method of pushing the module 11 downward while inserting the module 11 diagonally from above into the attachment unit.

According to the above-mentioned embodiment, a latch unit separate from a socket unit is not necessary because the force of dropping off a part upward does not work in an attaching method of pushing downward while inserting the part diagonally from above into the socket unit by the arrangement of the socket unit only. Therefore, the attachment area of the parts support apparatus can be reduced, and a parts support apparatus effective in downsizing the body device such as a personal computer etc. can be provided.

What is claimed is:

1. A parts support apparatus, comprising:
a part support hole for holding an aperture capable of inserting a part; and
a cavity that is provided in the part support hole and can be engaged with a part of the part inserted from the aperture into the part support hole.

2. The apparatus according to claim 1, wherein
the cavity is provided in a position in which the cavity is engaged with an insertion side end portion of the part when the part is inserted into an innermost of the part support holes

3. The apparatus according to claim 1, wherein
the part support hole into which the part is inserted is rectangular parallelepiped or cubic.

4. The apparatus according to claim 1, wherein
the part is a planar part and is provided with a plurality of contact points on an insertion side end portion inserted into the part support hole;
wherein the part support hole has a plurality of contact points in contact with the plurality of contact points provided for the insertion side end portion of the part.

5. The apparatus according to claim 1, further comprising
a drop protection member for preventing the part from dropping off the part support hole.

6. The apparatus according to claim 5, wherein
the drop protection member is provided for a cover member for covering the parts support apparatus, and touches an end surface opposite an insertion side end surface of the part after the part is inserted into the part support hole and attached thereto.

7. The apparatus according to claim 5, wherein
the drop protection member is a latch provided in the cavity formed innermost the part support hole.

8. The apparatus according to claim 5, wherein
the drop protection member is a latch provided as extending opposite the direction of inserting the part from both sides of the part support hole.
